(19) United States
(12) Patent Application Publication
(10) Pub. No.: US 2023/0135011 A1
(43) Pub. Date: May 4, 2023

(54) NEURON CIRCUIT, OPERATING METHOD THEREOF, AND NEUROMORPHIC DEVICE INCLUDING NEURON CIRCUIT

(71) Applicant: SEOUL NATIONAL UNIVERSITY R&DB FOUNDATION, Seoul (KR)

(72) Inventors: Byung-Gook PARK, Seoul (KR); Yeon Woo KIM, Seoul (KR)

(21) Appl. No.: 17/972,051

(22) Filed: Oct. 24, 2022

Related U.S. Application Data
(63) Continuation of application No. PCT/KR2022/013959, filed on Sep. 19, 2022.

(30) Foreign Application Priority Data
Nov. 4, 2021 (KR) 10-2021-0150781
Jun. 9, 2022 (KR) 10-2022-0070160

(51) Int. Cl. G06N 3/063

(52) U.S. Cl. CPC G06N 3/063

(57) ABSTRACT

Provided is a neuron circuit that including: an input unit and an output unit and processes a signal transmitted through a synaptic array. The input unit receives weighted signals transmitted through the synaptic array and integrates the weighted signals as input signals, and discharge the integrated input signals until the amount of integrated input signal is less than or equal to a preset threshold. The output unit receives a signal output from the input unit, performs up-counting, and then generates an output signal while performing down-counting.

### BACKGROUND

### 1. Field

The present disclosure relates to a neuron circuit, an operating method thereof, and a neuromorphic device including a neuron circuit, and more particularly, to a neuron circuit configured to count input/output signals based on a digital circuit, an operating method of the neuron circuit, and a neuromorphic device including the neuron circuit.

### 2. Description of the Related Art

A neuromorphic technology relates to an artificial neural network structure emerged by imitating the human brain and is a technology to solve problems such as computational inefficiency of the conventional Von Neumann computing architecture. A neuromorphic device consists of a combination of a neuron circuit and a synaptic array consisting of one or more synaptic elements. The synaptic array stores and calculates weights in an artificial neural network structure, and the neuron circuit processes a signal transmitted from the synaptic array and transmits the signal to a next synaptic array.

Since the conventional neuron circuit receives and outputs the spike signal in an analog method, signal loss occurs during a transmission process, and it is difficult to accurately investigate information in each neuron. Therefore, in order to solve this problem, a method to accurately measure the amount of information that is input and output for each neuron is requested.

### SUMMARY

The present disclosure provides a neuron circuit configured to count the amount of input and output signals based on a digital circuit, an operating method thereof, and a neuromorphic device including the neuron circuit.

Technical objects to be achieved by the present disclosure are not limited to the above-described technical object, and other technical objects of the present disclosure may be derived from the following descriptions.

An embodiment according to a first aspect of the present disclosure provides a neuron circuit, including an input unit and an output unit, that processes a signal transmitted through a synaptic array consisted of one or more synaptic element. The input unit configured to receive and integrate signals output from the synaptic array as input signals and discharge the integrated input signals until the amount of the integrated signal becomes less than or equal to a present threshold. The output unit configured to up-count while the input unit is discharging, and to generate an output signal while down-counting.

An embodiment according to a second aspect of the present disclosure provides a neuromorphic device including a synaptic array including one or more synaptic elements, and a neuron circuit connected to the synaptic array, wherein the neuron circuit includes an input unit configured to receive and integrate signals transmitted through the synaptic array or other device as input signals and discharge integrated input signals until an amount of the integrated input signals is less than or equal to a present threshold, and an output unit configured to perform up-counting in response to a signal output from the input unit, a first clock signal, and a second clock signal, and then generate an output signal while down-counting.

An embodiment according to a third aspect of the present disclosure provides an operating method of a neuron circuit which includes an integrator, a discharger, a comparator, a counter, and an output generator and a synaptic array consisted of one or more synaptic elements, wherein operations of the integrator and the discharger are controlled by a first clock signal and operations of the comparator, the counter, and the output generator are controlled by the first clock signal and a second clock signal, wherein the operating method includes receiving and integrating, by the integrator, the weighted signals through the synaptic array in a case in which the integrator is disconnected from the discharger and the integrator is disconnected from the comparator when a state of the first clock signal is in a high state, linearly discharging a signal corresponding to a preset discharge amount from an amount of the integrated input signals, comparing, by the comparator, a residual amount obtained by subtracting an amount of a signal discharged by the discharger from the amount of the integrated input signals with the previously specified threshold to transmit an up-counting maintenance signal to the counter until the residual amount is less than or equal to the threshold, and performing, by the counter, the up-counting in response to a signal received from the comparator and the second clock signal, in a case in which the integrator is connected to the discharger and the integrator is connected to the comparator when the state of the first clock signal is in a low state, and receiving and integrating, by the integrator, new weighted signals transmitted through the synaptic array, and generating, by the output generator, an output signal while performing down-counting, by the counter, in response to the second clock signal, in a case in which the integrator is disconnected from the discharger and the integrator is disconnected from the comparator when the state of the first clock signal is switched to the high state.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a neuron circuit according to an embodiment of the present disclosure and synapses connected the neuron circuit;

FIG. 2 is a block diagram illustrating a configuration of the neuron circuit illustrated in FIG. 1;

FIG. 3 is a block diagram illustrating sub-configurations of the configuration of the neuron circuit illustrated in FIG. 2;

FIGS. 4 to 6 are diagrams illustrating an example of an operation of the neuron circuit illustrated in FIG. 1; and

FIG. 7 is a flowchart illustrating an operating method of a neuron circuit, according to another embodiment of the present disclosure.

### DETAILED DESCRIPTION

Hereinafter, the present disclosure will be described in detail with reference to the accompanying drawings. However, the present disclosure may be implemented in various different forms and is not limited to the embodiments described herein. In addition, the accompanying drawings are only for easy understanding of the embodiments disclosed in the present specification, and the technical ideas disclosed in the present specification are not limited by the accompanying drawings. All terms including technical terms and scientific terms used herein should be interpreted in the meaning generally understood by those skilled in the art to which the present disclosure belongs. Terms defined in the dictionary should be interpreted as having additional meanings consistent with the related technical literature and the presently disclosed content, and are not interpreted in a very ideal or limiting sense unless otherwise defined.

In order to clearly describe the present disclosure, parts irrelevant to the description are omitted in the drawings, and sizes, shapes, and forms of each component illustrated in the drawings may be variously modified. The same/similar reference numerals are attached to the same/similar parts throughout the specification.

Suffixes “module”, “unit”, and “portion” for components used in the following description are given or used in consideration of only ease of writing the specification and do not have distinct meanings or roles by themselves. In addition, in describing the embodiments disclosed in the present specification, when it is determined that detailed descriptions of related known technologies may obscure the gist of the embodiments disclosed in the present specification, detailed descriptions thereof are omitted.

Throughout the specification, when a portion is “connected (coupled, contacted, or combined)” to another portion, this includes not only a case of being “directly connected (coupled, contacted, or combined)” but also a case of being “indirectly connected (coupled, contacted, or combined)” to another element interposed therebetween. In addition, when a portion “includes (comprises or provides)” a certain component, this means that other components may be further included (comprised or provided) therein rather than excluding other components, unless otherwise stated.

As used herein, terms indicating ordinal numbers such as first, second, and so on are used only for the purpose of distinguishing one element from another element, and do not limit a sequence or a relationship of elements. For example, a first component of the present disclosure may be referred to as a second component, and similarly, the second component may also be referred to as the first component. A form of a singular expression used herein should be construed as including forms of plural expressions as well, unless the meaning is clearly indicated to the contrary.

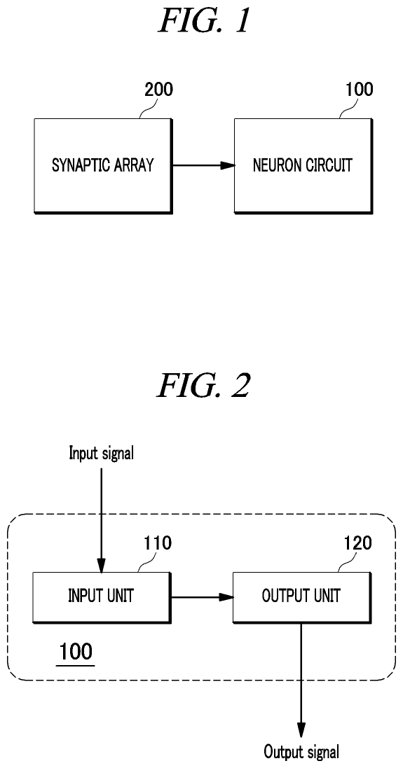

FIG. 1 is a diagram illustrating a neuron circuit 100 and a synaptic array 200 connected to the neuron circuit 100 according to an embodiment of the present disclosure.

Referring to FIG. 1, the neuron circuit 100 may be connected to the synaptic array 200. The synaptic array 200 may be configured to include one or more synaptic elements. The synaptic element is implemented to perform the same function as a brain synapse and is generally implemented based on a non-volatile memory device. The synaptic array corresponds to a plurality of synaptic cells, and each of the synaptic cells stores a predetermined weight. The synaptic array may be connected to pre-neuron circuits and post-neuron circuits, and the synaptic array may include synaptic cells corresponding to a multiplication of the number of pre-neuron circuits and the number of post-neuron circuits. An operation of storing weights in the synaptic array or a process of reading the stored weights from the synaptic array 210 is performed through the same principle as a program operation or a read operation performed in a general nonvolatile memory device. Here, the weight means a weight that is multiplied by an input signal in a perceptron structure or so on representing an artificial neural network model and is additionally defined as a concept including a bias which is a special weight with an input of 1. The neuron circuit 100 and the synaptic array 200 may constitute a neuromorphic device and may each include one or more electrical elements, electronic elements, and semiconductor elements. For example, the neuron circuit 100 and the synaptic array 200 may each include one or more elements among a capacitor, a memristor, and a transistor.

The synaptic array 200 and the neuron circuit 100 may be connected in series and in parallel as a unit. In this case, the neuron circuit 100 may receive a weighted signal transmitted from the synaptic array 200 as an input signal and may transmit an output signal to the next synaptic array connected to an output terminal.

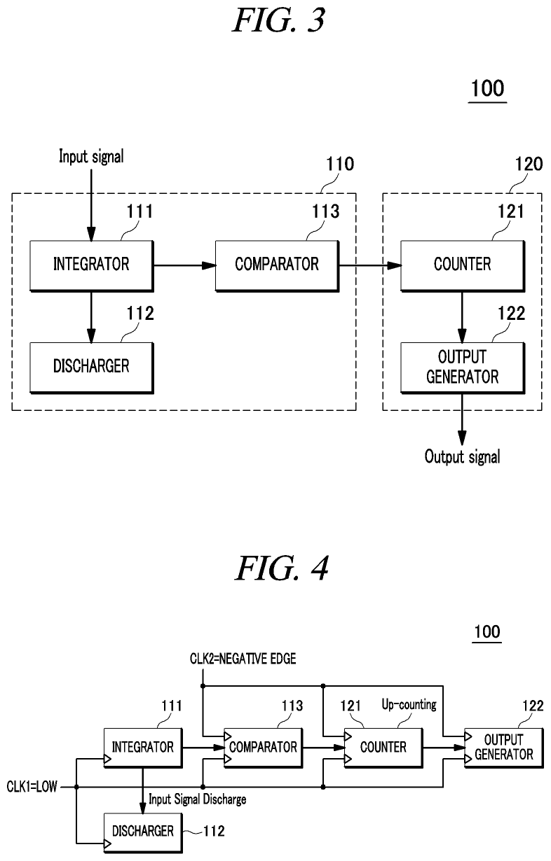

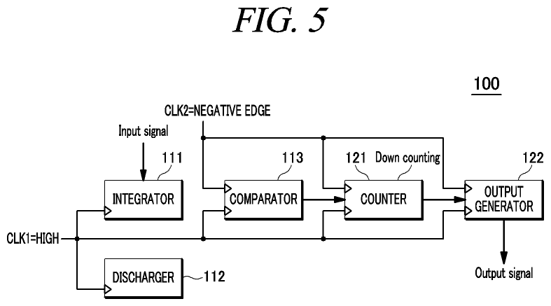

FIG. 2 is a block diagram illustrating a configuration of the neuron circuit 100 illustrated in FIG. 1, and FIG. 3 is a block diagram illustrating sub-configurations of the configuration of the neuron circuit 100 illustrated in FIG. 2.

Referring to FIG. 2, the neuron circuit 100 includes an input unit 110 that receives an input signal and an output unit 120 that generates an output signal.

The input unit 110 receive weighted signals transmitted through the synaptic elements by receiving a pulse generated from a previous neuron or another device and integrates the signals. In addition, the input unit 110 discharges the integrated input signals until the amount of the integrated signals is less than or equal to a preset threshold. The output unit 120 receives a signal output from the input unit 110 to perform up-counting. In addition, the output unit 120 generates an output signal while performing down-counting. The up-counting means that a counter 121 receives a signal output from a comparator 113 and performs numbering from n0 (n0 is the smallest integer that the counter may represent) to n (n is an integer greater than n0). The down-counting means that the counter 121 performs numbering from n (n is an integer greater than n0) to n0 (n0 is the smallest integer that the counter may represent).

Referring to FIG. 3, the input unit 110 includes an integrator 111, a discharger 112, and a comparator 113. The integrator 111 integrates an input signal. The discharger 112 discharges a signal equal to a preset discharge amount from the integrated input signals until the amount of integrated signals is lower than the threshold. The comparator 113 compares the threshold with a residual amount obtained by subtracting the amount of the signals discharged by the discharger 112 from the amount of integrated input signals. Furthermore, the comparator 113 transmits a signal to the output unit 120 until the residual amount is less than or equal to the threshold.

The output unit 120 includes the counter 121 and an output generator 122. The counter 121 performs up-counting in response to a signal transmitted by the comparator 113 and then performs down-counting. The output generator 122 receives a signal output from the counter 121 and generates an output signal, and then outputs the generated output signal to a synaptic array of a neuron layer when there is a connected neuron layer.

Here, the synaptic array may refer to a next synaptic array connected to the output generator 122.

The operations of the neuron circuit 100 described above, and states and input/output of signals may be controlled by a separate controller. In addition, numerical values such as the threshold and the discharge amount described above may be set to various values by the controller before the operations of the neuron circuit 100 are performed.

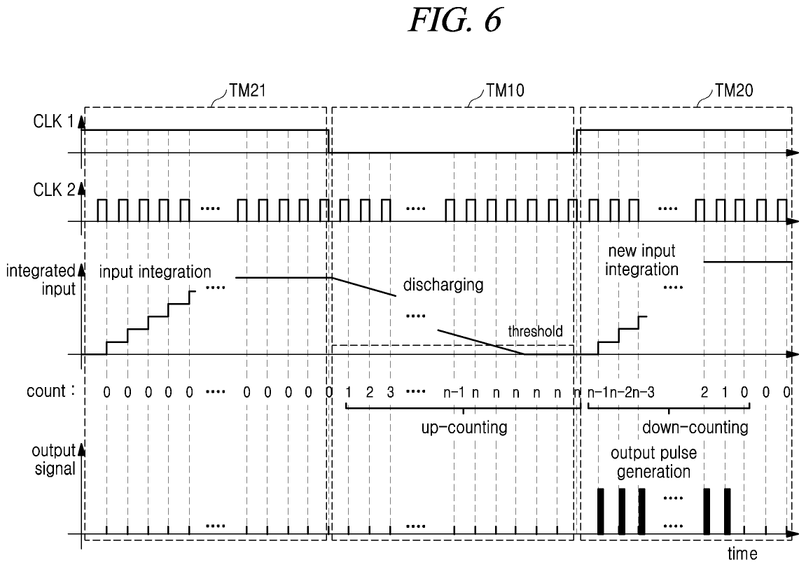

An example of an operation method will be described with reference to FIGS. 4 to 6 illustrated to describe examples of operations of the neuron circuit 100. FIG. 4 illustrates an example of operation states of the neuron circuit 100 when a state of a first clock signal CLK1 is a low state. FIG. 5 illustrates an example of operation states of the neuron circuit 100 when the state of the first clock signal CLK1 is a high state. FIG. 6 illustrates an operation timing diagram of the neuron circuit 100 according to the first clock signal CLK1 and a second clock signal CLK2. The timing diagram illustrated in FIG. 6 includes a timing diagram TM10 when the first clock signal CLK1 is in a low state, a timing diagram TM20 when the first clock signal CLK1 is in a high state, and a timing diagram TM21 when an operation of the neuron circuit 100 starts, which is one of special cases in which the first clock signal CLK1 is in a high state TM20. The operations of the neuron circuit 100 described below may be modified in various examples according to a combination of the first and second clock signals.

Referring to FIGS. 4 to 6, in one example, operations of the integrator 111 and the discharger 112 may be controlled by the first clock signal CLK1, and operations of the comparator 113, the counter 121, and the output generator may be controlled by the first clock signal CLK1 and the second clock signal CLK2. In this case, each of the integrator 111 and the discharger 112 may include a terminal to which the first clock signal CLK1 is input. The comparator 113, the counter 121, and the output generator 122 may each include a terminal to which the first clock signal CLK1 is input and a terminal to which the second clock signal CLK2 is input. As such, the first clock signal CLK1 may be input to one terminal of the integrator 111 and one terminal of the discharger 112. The first clock signal CLK1 may be input to one terminal of the comparator 113, one terminal of the counter 121, and one terminal of the output generator 122, and the second clock signal CLK2 may be input to the other terminal of the comparator 113, the other terminal of the counter 121, and the other terminal of the output generator 122.

When the first clock signal CLK1 is in a low state, the integrator 111 is connected to the discharger 112, and the integrator 111 is connected to the comparator 113. The discharger 112 discharges a signal corresponding to a preset discharge amount from the amount of the input signals integrated by the integrator 111. The comparator 113 transmits a signal to the counter 121 until the residual amount, which is obtained by subtracting the amount of the signal discharged by the discharger 112 from the amount of the integrated input signals, is less than or equal to a preset threshold. The counter 121 performs up-counting when there is a signal transmitted from the comparator 113 in response to the second clock signal CLK2. An operation of the counter 121 may be performed whenever the second clock signal CLK2 is in a negative edge state. The up-counting may be performed from n0 (n0 is the smallest integer that a counter may represent) to n (n is an integer greater than n0). When the residual amount is less than or equal to a preset threshold, the comparator 113 stops transmitting a signal to the counter 121 and the up-counting ends.

When a state of the first clock signal CLK1 is a high state, the integrator 111 is disconnected from the discharger 112, and the integrator 111 is disconnected from the comparator 113. The integrator 111 receives weighted signals transmitted through the synaptic array 200 as input signals and integrates the signals. The counter 121 performs down-counting of a previously stored number through up-counting in response to the second clock signal CLK2 and transmits the signal to the output generator 122. The output generator 122 generates an output signal when there is a signal output from the counter 121 in response to the second clock signal CLK2, and then transmits the output signal to a next synaptic array connected to the output generator. Operations of the counter 121 and the output generator 122 may be performed whenever the second clock signal CLK2 is in a negative edge state. The down-counting may be performed from n (n is an integer greater than n0) to n0 (n0 is the smallest integer that a counter may represent). When the number stored in the counter 121 reaches n0, the down-counting ends.

A neuromorphic device including the above-described neuron circuit 100 may be provided as an embodiment of the present disclosure. The neuromorphic device may be implemented by using the synaptic array 200 and the neuron circuit 100 as one unit to connect a plurality of units in series and in parallel.

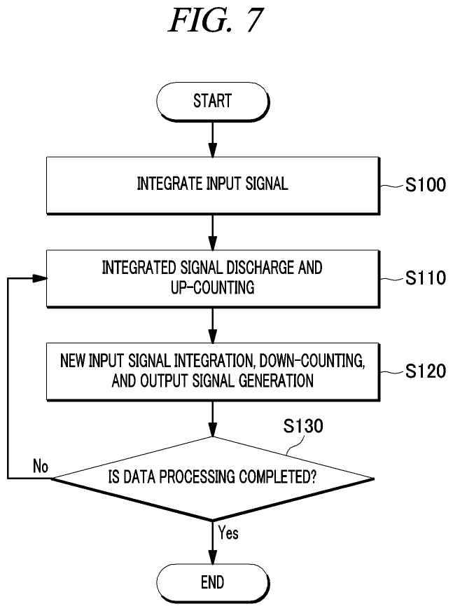

FIG. 7 is a flowchart illustrating a method of operating a neuron circuit (hereinafter, referred to as an “operation method of a neuron circuit”) according to another embodiment of the present disclosure. The operating method of a neuron circuit may be an operating method of a neuron circuit which processes a signal transmitted through a synaptic array and include an integrator and a discharger of which operations are controlled by a first clock signal, a comparator and a counter of which operations are controlled by the first and second clock signals, and an output generator of which operation is controlled by the second clock signal. Here, the neuron circuit may be the neuron circuit 100 of FIG. 1 described above with reference to FIGS. 1 to 6. In addition, an integrator, a discharger, a comparator, a counter, and an output generator may be respectively the integrator 111 in FIG. 3, the discharger 112 in FIG. 3, the comparator 113 in FIG. 3, the counter 121 in FIG. 3, the output generator 122 in FIG. 3, which are described above.

Referring to FIG. 7, the operation method of the neuron circuit may include an input signal integration step S100, an integrated-signal discharging and up-counting step S110, a new input signal integration and down-counting and output signal generation step S120, and a data processing completion determining step S130. The integrated-signal discharging and up-counting step S110 and the new input signal integration and down-counting and output signal generation step S120 may be performed repeatedly.

The input signal integration step S100 is a first step of a neuron circuit operation. In the input signal integration step S100, when a state of a first clock signal is in a high state, the integrator is disconnected from the discharger, and the integrator is disconnected from the comparator. In the input signal integration step S100, the integrator receives signals transmitted through the synaptic array and integrates the signal, but the counter does not perform down-counting because up-counting is not performed previously, and an output signal is not generated by the output generator.

In the integrated-signal discharging and up-counting step S110, when the state of the first clock signal is in a low state, the integrator is connected to the discharger, and the integrator is connected to the comparator. In the integrated-signal discharging and up-counting step S110, the discharger linearly discharges signals as much as a preset discharge amount from the amount of the integrated signals, and the comparator compares a preset threshold with a residual amount obtained by subtracting the amount of signal discharged by the discharger from the amount of integrated signals and transmits signals to the counter until the residual amount is less than the threshold, and the counter performs up-counting in response to the signal received from the comparator and a second clock signal.

In the new input signal integration and down-counting and output signal generation step S120, when the state of the first clock signal is in a high state, the integrator is disconnected from the discharger, the integrator is connected to the comparator, the integrator receives new weighted signals transmitted through a synaptic array and integrates the new weighted signals, and the counter generates an output signal through the output generator in response to the second clock signal while down-counting is performed.

In the data processing completion determining step S130, after the new input signal integration and down-counting and output signal generation step S120 is completed, when it is determined that there is no more data to be processed, the operation of the neuron circuit ends, and when there is data to be processed, the operation of the neuron circuit proceeds to the integrated-signal discharging and up-counting step S110.

In other words, when a first clock signal is high, input signals are integrated while generating an output signal, and when the first clock signal is low, the integrated input signals are counted. An operation of a neuron circuit begins with an input signal integration step, and at this time, down-counting and output signal generation are not performed because up-counting is not performed previously. Thereafter, the integrated signals are linearly discharged by connecting an integrator to a comparator and connecting the integrator to a discharger. In addition, a threshold is compared with a residual amount obtained by subtracting the amount of discharged signal from the amount of integrated signals in the comparator for every second clock, and when the residual amount is greater, up-counting is performed. Thereafter, the integrator is disconnected from the comparator and the integrator is disconnected from the discharger, and the counter outputs an output signal while down-counting is performed for every second clock signal. In this case, the integrator integrates new input signals. Thereafter, when there is data to be processed, an operation of a neuron circuit proceeds to an integrated-signal discharging and up-counting step to repeat the described operations, and when all data is processed, the operation of the neuron circuit ends.

A neuron circuit according to the embodiment of the present disclosure described above operates separately at a time at which input signals are integrated while an output signal is output in response to a first clock signal, and a time at which a counter measures the amount of input signals while the integrated input signals are discharged. During the input signal integration time, an integrator is disconnected from a discharger to integrate input signals input through a synaptic array, and while down-counting is performed until the number stored in the counter becomes n0 (n0 is the smallest integer that the counter may represent) every second clock signal, an output signal is transmitted to the next synaptic array connected to an output terminal. At the time at which the input signal is measured, the integrator is connected to the discharger to linearly discharge the integrated signals, and up-counting is performed every second clock signal until the up-counted value falls below a preset threshold, and the up-counted value is stored in the counter. When an artificial neural network is implemented by using the neuron circuit according to embodiments of the present disclosure, all neuronal circuits may operate in response to the first clock signal.

Those skilled in the art to which the present disclosure pertains will be able to understand that the present disclosure may be easily modified into other specific forms without changing the technical idea or essential features of the present disclosure based on the above description. Therefore, it should be understood that the embodiments described above are illustrative in all respects and not restrictive. The scope of the present disclosure is indicated by the following claims, and all changes or modifications derived from the meaning and scope of the claims and their equivalents should be construed as being included in the scope of the present disclosure. The scope of the present application is indicated by the following claims rather than the above detailed description, and all changes or modifications derived from the meaning and scope of the claims and their equivalents should be construed as being included in the scope of the present application.

According to the present disclosure, the amount of input/output information for each neuron may be accurately measured by adding a digital logic for counting to a neuron circuit.

In addition, according to the present disclosure, a time at which each neuron of a neuron circuit receives an input signal is separated from a time at which the integrated input signals are discharged and the amount of integrated input signals is counted. In this way, by separating a time for receiving information from a time for calculating the input information, an inference operation may be performed in a pipeline format, and thereby, a time required for inference may be reduced to construct an artificial neural network that enables parallel inference operations.

In addition, according to the present disclosure, each neuron circuit may know a calculation value in a synapse for an input, and thus, errors and signal distortion problems caused by variables of circuits and devices may be corrected for each layer.

In addition, according to the present disclosure, unlike the known spiking neural network (SNN) manner, a technique such as max pooling used in a general artificial neural network may be used based on data counted by each neuron, and thus, inference performance of the neural network may be further improved.

The known neural network does not receive the next data until one piece of information is input and then output, and thereby, inference time is lengthened, but when the neuron circuit proposed by the present disclosure is used, one piece of data may pass through a first layer to be output and the next data may be input at the same time. Accordingly, after the first data is output, the next data is output for every clock signal, and thus, inference throughput may increase. When an artificial neural network is implemented by using a neuron circuit according to an embodiment of the present disclosure, an efficient calculation may be performed through an analog method, and an output signal may be accurately transmitted through a digital logic.

In addition, a neuron circuit according to the present disclosure uses a simple counter circuit compared to the known analog to digital converter (ADC) circuit, and thus, a more compact neuromorphic device than the known neuron circuit may be implemented.

In addition, a neuron circuit according to the present disclosure operates by mixing an analog method with a digital method, and thus, the neuron circuit has a stronger advantage than the known neuron circuit with respect to a change according to external a factor such as a temperature, and may be used as an ADC or a digital to analog converter (DAC) circuit in other circuits other than a neuromorphic device.

### MODE FOR IMPLEMENTING THE INVENTION

A mode for implementing the disclosure is the same as the best mode for implementing the disclosure described above.

### INDUSTRIAL APPLICABILITY

The present disclosure has industrial applicability because the present disclosure may be used in a neuromorphic-related industry as a technology for a neuron circuit and a neuromorphic device.

What is claimed is:

1. A neuron circuit that processes a signal transmitted through a synaptic array, the neuron circuit comprising:
an input unit configured to receive and integrate signals output from the synaptic array as input signals and discharge the integrated input signals until an amount of the integrated signals is less than or equal to a preset threshold; and
an output unit configured to receive a signal output from the input unit to perform up-counting and generate an output signal while down-counting is performed.

2. The neuron circuit of claim 1, wherein the input unit comprises:
an integrator configured to integrate the input signals;
a discharger configured to linearly discharge a signal corresponding to a preset discharge amount from the integrated input signals until the amount of the integrated signals is less than or equal to the threshold; and
a comparator configured to compare the threshold with a residual amount obtained by subtracting an amount of signal discharged by the discharger from an amount of the integrated input signals and transmit a signal to the output unit until the residual amount is less than or equal to the threshold.

3. The neuron circuit of claim 2, wherein the output unit comprises:
a counter configured to receive a signal output from the comparator to perform the up-counting and then perform the down-counting; and
an output generator configured to receive a signal output from the counter to generate an output signal and output the generated output signal to a synaptic array connected to an output terminal.

4. The neuron circuit of claim 3, wherein
operations of the integrator and the discharger are controlled by a first clock signal, and
operations of the comparator, the counter, and the output generator are controlled by the first clock signal and a second clock signal.

5. The neuron circuit of claim 4, wherein,
when a state of the first clock signal is a low state,
the integrator is connected to the discharger, the integrator is connected to the comparator,
the discharger linearly discharges a signal corresponding to a discharge amount from the amount of the integrated input signals,
the comparator transmits an up-counting maintenance signal to the counter in response to the second clock signal until the residual amount is less than or equal to the threshold, and
wherein the counter performs up-counting in response to the up-counting maintenance signal and the second clock signal received from the comparator.

6. The neuron circuit of claim 4, wherein,
when a state of the first clock signal is in a high state,
the integrator is disconnected from the discharger, and the integrator is disconnected from the comparator,
the integrator receives and integrates the input signals, and
the counter generates an output signal through the output generator in response to the second clock signal while the down-counting is performed.

7. A neuromorphic device comprising:
a synaptic array including one or more synaptic elements; and
a neuron circuit connected to the synaptic array,
wherein the neuron circuit includes an input unit configured to receive and integrate signals transmitted through the synaptic array as input signals and discharge integrated input signals until an amount of the integrated input signals is less than or equal to a preset threshold, and an output unit configured to perform up-counting in response to a signal output from the input unit, a first clock signal, and a second clock signal, and then generate an output signal while performing down-counting.

8. The neuromorphic device of claim 7, wherein the input unit comprises:
an integrator configured to integrate the input signals;
a discharger configured to linearly discharge a signal corresponding to a preset discharge amount from the integrated input signals until the amount of the integrated signals is less than or equal to the threshold; and
a comparator configured to compare the threshold with a residual amount obtained by subtracting an amount of signal discharged by the discharger from the amount of the integrated input signals and transmit a signal to the output unit until the residual amount is less than or equal to the threshold.

9. The neuromorphic device of claim 8, wherein the output unit comprises:
a counter configured to perform the up-counting in response to the signal output from the comparator and the first clock signal and the second clock signal, and then perform the down-counting and transmits a signal to an output generator; and
the output generator configured to receive the signal output from the counter to generate the output signal and output the generated output signal to a next synaptic array connected to an output terminal.

10. The neuromorphic device of claim 9, wherein
operations of the integrator and the discharger are controlled by a first clock signal, and
operations of the comparator, the counter, and the output generator are controlled by the first clock signal and a second clock signal.

11. The neuromorphic device of claim 10, wherein
when a state of the first clock signal is a low state,
the integrator is connected to the discharger, the integrator is connected to the comparator,
the discharger linearly discharges a signal corresponding to a discharge amount from the amount of the integrated input signals,
the comparator transmits a signal to the counter until the residual amount is less than or equal to the preset threshold, and
the counter performs the up-counting in response to the second clock signal and the signal of the comparator.

12. The neuromorphic device of claim 10, wherein
when a state of the first clock signal is in a high state,
the integrator is disconnected from the discharger, and the integrator is disconnected from the comparator,
the integrator receives and integrates the input signals, and
the counter generates an output signal through the output generator while performing the down counting.

13. An operating method of a neuron circuit which includes an integrator, a discharger, a comparator, a counter, and an output generator and processes a signal transmitted through a synaptic array, wherein operations of the integrator and the discharger are controlled by a first clock signal and operations of the comparator, the counter, and the output generator are controlled by the first clock signal and a second clock signal, the operating method comprising:
receiving, by the integrator, weighted signals transmitted through the synaptic array and integrating the weighted signals, in a case in which the integrator is disconnected from the discharger and the integrator is disconnected from the comparator when a state of the first clock signal is in a high state;
receiving input signals integrated by the integrator, linearly discharging a signal corresponding to a preset discharge amount from an amount of the integrated input signals, comparing, by the comparator, a residual amount obtained by subtracting an amount of a signal discharged by the discharger from the amount of the integrated input signals with a preset threshold to transmit an up-counting maintenance signal to the counter until the residual amount is less than or equal to the preset threshold, and performing, by the counter, the up-counting in response to a signal received from the comparator and the second clock signal, in a case in which the integrator is connected to the discharger and the integrator is connected to the comparator when the state of the first clock signal is in a low state; and
receiving, by the integrator, new weighted signals transmitted through the synaptic array, integrating the new weighted signals, and generating, by the counter, an output signal through the output generator while performing down-counting in response to the second clock signal, in a case in which the integrator is disconnected from the discharger and the integrator is disconnected from the comparator when the state of the first clock signal is switched to the high state.
